(19) United States
(12) Patent Application Publication
(10) Pub. No.: US 2005/0199582 A1
(43) Pub. Date: Sep. 15, 2005

(54) Method for forming fine grating

(75) Inventor: Kazuhiro Miyakawa, Miyagi-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/072,564

(22) Filed: Mar. 3, 2005

(30) Foreign Application Priority Data
Mar. 9, 2004 (JP) 2004-065866

(51) Int. Cl. B29D 11/00; C30B 1/00; H01L 21/20; H01L 21/36

(52) U.S. Cl. 216/24

(57) ABSTRACT

A method for forming a fine grating on a substrate has the steps of forming a first mask film having fine grooves corresponding to a pattern of the fine grating on a surface of the substrate, forming a second mask film over the first mask film so as to form fine recess portions having a smaller width than that of the fine grooves of the first mask film at positions at which the fine grooves are located, etching the second mask film so as to enable the fine recess portions to reach the surface of the substrate while the widths of the fine recess portions are each approximately uniformly maintained, and etching parts of the substrate which are exposed through the recess portions by etching of the second mask film, whereby the fine grating is formed.

This application claims the benefit of priority to Japanese Patent Application 2004-065866, filed on Mar. 9, 2004, which is incorporated herein by reference.

### TECHNICAL FIELD

The present application relates to methods for forming a fine grating on a substrate, and more particularly, relates to methods for forming a fine grating on a substrate by etching.

### BACKGROUND

In recent years, optical members such as lenses and diffraction gratings have been generally formed by electroforming of a model material of an optical member to produce a mold therefor, followed by injection molding using the mold.

In the method described above, in order to prevent optical reflection on an optical surface of the optical member, an antireflection grating having a period of one-half or less of the wavelength of incident light is provided on the optical surface in some cases. In order to form the antireflection grating on the optical surface of the optical member, an antireflection grating must also be formed on the model material of the forming the mold.

A method for forming a fine grating, such as the antireflection grating described above, on a substrate surface, for example, is disclosed in Japanese Unexamined Patent Application Publication No. 9-254161 in which etching is performed for a substrate surface to form a fine grating. In particular a mask film made of silicon dioxide is formed on the substrate. A resist is applied to this mask film, and an pattern corresponding to a pattern of the fine grating is drawn on the resist using an exposure apparatus, followed by development of this original pattern, thereby forming a resist pattern in which resist portions and fine grooves are alternately repeated at intervals in accordance with the pattern of the fine grating. Subsequently, by using the resist having the resist pattern described above as an etching mask, etching is performed for the mask film, so that a mask pattern having fine groves is formed in the mask film. Next, when the resist is removed, only the mask film having the mask pattern thus formed remains on the substrate.

By using this mask film as an etching mask, etching of the substrate and, as a result, parts of the substrate exposed through the fine grooves are etched. When being etched in the thickness direction, the substrate is also etched in the width direction, and hence tapered grooves are formed having a width which gradually decreases in the thickness direction, so that remaining parts which are not etched form a fine grating.

As described above, since the substrate is simultaneously etched in the thickness and the width directions, when the etching of the substrate proceeds to places at which front ends of the fine grating are formed, the substrate is no longer protected by the etching mask, and the entire substrate is etched; hence, even when further etching is carried out, grooves having a larger depth cannot be formed. When the substrate is made of silicon, the phenomenon described above becomes more significant since etching is likely to proceed in the width direction. In addition, when the grooves having a larger depth are not formed as described above, a fine grating having a desired shape may not be obtained in some cases.

Accordingly, in order to form a fine grating having a desired shape, widths of fine grooves forming a mask pattern of the mask film must be decreased so as to decrease the widths of the grooves formed in the substrate. That is, in order to form a mask pattern composed of fine grooves having a small width in the mask film, the widths of the fine grooves formed in the resist must be decreased.

However, the minimum dimensional unit of an original pattern which can be drawn on a resist is determined by the performance of an exposure apparatus, and when a fine original pattern is to be drawn, an expensive exposure apparatus such as an electron beam exposure apparatus must be used. In addition, since the formation of an original pattern by an electron beam exposure apparatus takes a long time, a time required for processing the substrate becomes long, and as a result, a unfavorable decrease in working efficiency has occurred.

### SUMMARY

A method for forming a fine grating is described, in which grooves having a small width can be formed in a substrate in a short period of time using an inexpensive apparatus and in which a fine grating having a desired shape can be formed.

A method for forming a fine grating on a surface of a substrate by etching, which comprises: forming a first mask film having a pattern of fine grooves on the surface of the substrate, the pattern corresponding to the fine grating; forming a second mask film having fine recess portions over the first mask film, the fine recess portions having a smaller width than that of the fine grooves and being disposed at positions at which the fine grooves of the first mask film are located; etching the second mask film so as to enable the fine recess portions to reach the surface of the substrate while the widths of the fine recess portions are each approximately uniformly maintained; and etching parts of the substrate which are exposed through the recess portions by etching of the second mask film so as to form the fine grating.

In addition, according to the method described above, the second mask film is preferably formed of silicon dioxide and may be etched by dry etching, so that the fine recess portions reach the surface of the substrate while the widths of the recess portions are each approximately uniformly maintained.

In another aspect, the second mask film may be processed by ion milling for etching, so that the fine recess portions reach the surface of the substrate while the widths of the recess portions are each approximately uniformly maintained.

In another aspect, a metal film having a hole pattern of a plurality of fine holes may be disposed or may be formed on the substrate, the hole pattern being formed by anodization so as to correspond to the fine grating, and after a thin film is formed over the metal film, the metal film may be removed so as to form the first mask film having finely spaced holes.

Even when an inexpensive exposure apparatus is used, in which the minimum dimensional unit of an original pattern which can be drawn on a resist is large, an etching mask provided with fine grooves having a desired width can be formed. Accordingly, grooves having a small width can be formed in the substrate at low cost, and as a result, a fine grating having a desired shape can be formed at low cost. In addition, the fine grating as described above can be formed in a short period of time.

In yet another aspect, silicon dioxide is used for the second mask film and dry etching is performed therefor as described above. Since silicon dioxide is likely to be etched in the thickness direction and is less likely to be etched in the width direction, the fine recess portions of the second mask film are likely to reach the surface of the substrate while the widths of the recess portions are each approximately uniformly maintained, and as a result, an etching mask having a mask pattern of fine grooves, each of which has a desired width, can be easily formed.

Further, the second mask film may be processed by ion milling as described above. However, since etching in the thickness direction is easily performed by ion milling and etching in the width direction is not easily performed by ion milling, the fine recess portions of the second mask film are likely to reach the surface of the substrate while the widths of the recess portions are each approximately uniformly maintained, and as a result, an etching mask having a mask pattern of fine grooves, each of which has a desired width, can be easily formed.

In addition, the first mask film having fine grooves is formed using the metal film and the thin film as described above. The steps of applying a resist, drawing an original pattern, and developing an original pattern can be omitted, and as a result, the manufacturing process can be simplified.

### BRIEF DESCRIPTION OF THE DRAWINGS

FIGS. 1A to 1I are cross-sectional views each showing a model material for illustrating a step of forming an antireflection grating on a model material, according to a first embodiment;

FIGS. 2A and 2B are cross-sectional views each showing a model material for illustrating a step of forming an antireflection grating, according to a second embodiment; and

FIGS. 3A to 3C are cross-sectional views each showing a model material for illustrating a step of forming a first mask film using an anodized aluminum film.

### DETAILED DESCRIPTION

Exemplary embodiments may be better understood with reference to the drawings, but these embodiments are not intended to be of a limiting nature. Like numbered elements in the same or different drawings perform equivalent functions.

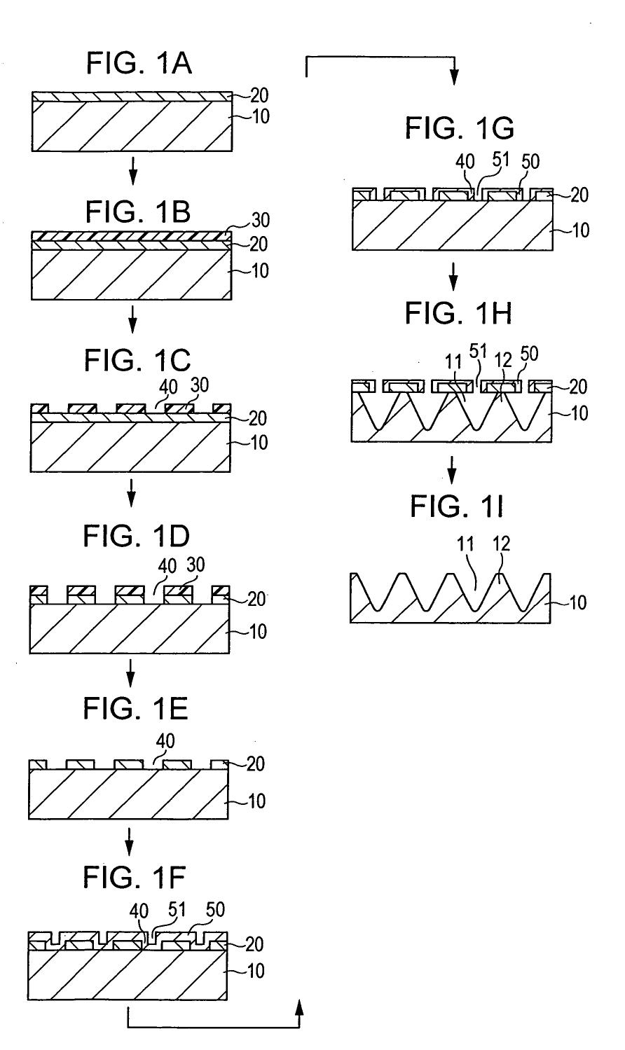

FIGS. 1A to 1I are cross-sectional views each showing a model material for illustrating a step of forming an antireflection grating on a model material, according to the first embodiment. A model material 10 is formed of silicon and is used for forming a mold which is used for injection molding of an optical member, and the mold is formed by electroforming of this mold material 10.

A first mask film 20 made of silicon dioxide is formed on a surface of the model material 10 using sputtering, chemical vapor deposition (CVD), or the like (FIG. 1A). This first mask film 20 is used as an etching mask for the model material 10. In this step, the material for the first mask film 20 is not limited to silicon dioxide and other materials, such as chromium which is frequently used as a material for an etching mask, may also be used.

A mask pattern having fine grooves 40 corresponding to the antireflection grating 12 is formed in the first mask film 20. A resist 30 is applied onto the first mask film 20 (FIG. 1B). Next, an original pattern corresponding to the above fine grooves 40 is drawn on the resist 30 using an exposure apparatus, followed by development of the original pattern, thereby forming a resist pattern in which resist portions and the fine grooves 40 are alternately repeated with intervals corresponding to the pattern of the antireflection grating 12 (FIG. 1C).

By using the resist 30 having a resist pattern formed of the fine grooves 40 as an etching mask, dry etching is performed for the first mask film 20 using an etching gas such as a fluorinated gas. Parts of the first mask film 20 exposed through the fine grooves 40 of the resist 30 are etched and removed so that the fine grooves 40 reach the surface of the model material 10, thereby forming the mask pattern in the first mask film 20 (FIG. 1D). After the mask pattern is formed in the first mask film 20, the resist 30 is removed (FIG. 1E).

A second mask film 50 made of silicon dioxide is formed over the first mask film 20 having the mask pattern formed of the fine grooves 40 (FIG. 1F). Since the first mask film 20 has the fine grooves 40, when the second mask film 50 is formed over the first mask film 20, parts of the second mask film 50 formed at the positions of the fine grooves 40 of the first mask film 20 are recessed in the fine grooves 40, and as a result, as shown in FIG. 1F, the parts of the second mask film 50 present in the fine grooves 40 of the first mask film 20 form fine recess portions 51 having a smaller width than that of the fine grooves 40.

In the state described above, dry etching is performed for the second mask film 50 using an etching gas. Since silicon dioxide is likely to be etched in the thickness direction and is less likely to be etched in the width direction, the second mask film 50 is approximately uniformly etched in the thickness direction, and as a result, the fine recess portions 51 reach the surface of the model material 10 while the widths of the recess portions 51 are each approximately uniformly maintained. Accordingly, the model material 10 is partially exposed through the fine recess portions 51 (FIG. 1G).

By using the first mask film 20 and the second mask film 50 as an etching mask, dry etching is performed for the model material 10 using an etching gas (FIG. 1H). Parts of the model material 10 exposed through the fine recess portions 51 are etched. Since silicon is likely to be etched both in the thickness and the width directions, when the etching of the model material 10 proceeds, as shown in FIG. 1H, tapered grooves 11 are formed having a width which is gradually decreased in the thickness direction. Hence, parts of the model material 10, which are not etched and remain, form cone shapes, thereby forming the antireflection grating 12. Finally, after the antireflection grating 12 is formed, the first mask film 20 and the second mask film 50 are removed using a hydrofluoric-acid processing machine or the like (FIG. 1I).

As described above, when the fine recess portions 51 having a width smaller than that of the fine grooves 40 are formed by forming the second mask film 50 over the first mask film 20 having the fine grooves 40, followed by etching, the etching mask can be formed, which has fine grooves having a width smaller than that of the fine grooves 40 of the first mask film 20, on the model material 10. Accordingly, the tapered grooves 11 having a small width can be formed in the model material 10, and the antireflection grating 12 can be formed so as to have a desired shape. In addition, after the fine grooves 40 are formed in the first mask film 20 to have a large width, the width thereof is decreased by film formation, and hence an inexpensive exposure apparatus can be used in which the minimum dimensional unit of an original pattern which can be drawn on the resist is large.

In the embodiment described above, the second mask film 50 is formed from silicon dioxide, and the properties thereof are used in which etching is likely to be performed in the thickness direction and is less likely to be performed in the width direction; hence, the second mask film 50 can be etched so that the fine recess portions 51 reach the surface of the model material 10 while the widths of the recess portions 51 are approximately uniformly maintained. However, even when another film material which does not have properties similar to those described above is used for the second mask film 50, the fine recess portions 51 can be formed so as to reach the surface of the model material 10 while the widths of the recess portions 51 are each approximately uniformly maintained.

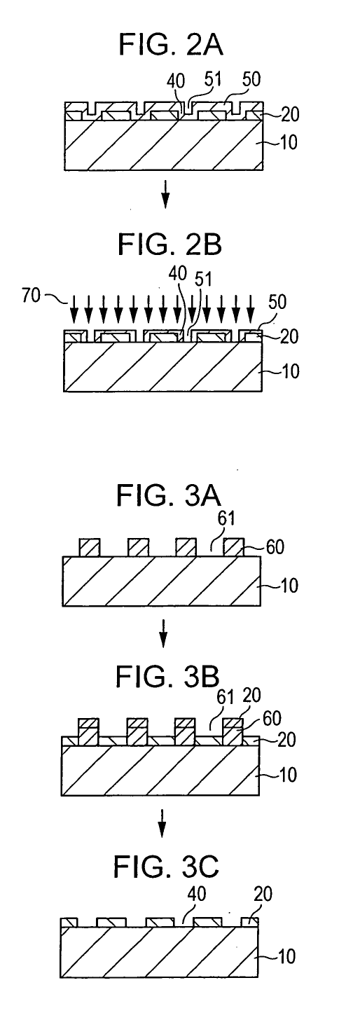

A second embodiment will be described in which another film material can be selected for the second mask film 50. FIGS. 2A and 2B are cross-sectional views each showing a model material for illustrating the forming an antireflection grating.

In this embodiment, since a step of forming the fine grooves 40 in the first mask film 20 and the preceding steps are equivalent to those described in the above first embodiment (FIGS. 1A to 1E), the description thereof will be omitted.

Over the first mask film 20, as is the case of the first embodiment, the second mask film 50 is formed so as to form the fine recess portions 51 (FIG. 2A). However, the material for this second mask film 50 is not limited to silicon dioxide, and another material such as chromium may also be used.

In addition, the second mask film 50 is etched by ion milling so as to enable the fine recess portions 51 to reach the surface of the model material 10 while the widths of the recess portions 51 are each approximately uniformly maintained (FIG. 2B). In this step, the ion milling is a processing method for etching a workpiece by radiating ion beams 70 such as Ar ion beams, and by this ion milling, the workpiece is etched in the thickness direction but is not substantially etched in the width direction. Thus, when being irradiated with the ion beams 70, the second mask film 50 is uniformly etched in the thickness direction, and hence the fine recess portions 51 can reach the surface of the model material 10 while the widths of the recess portions 51 are each approximately uniformly maintained.

Since a subsequent step of etching the model material 10 is equivalent to that described in the above first embodiment, the description will also be omitted.

In the first and the second embodiments described above, by etching the first mask film 20 using the resist 30 as an etching mask, the mask pattern is formed in the first mask film 20. However, by using another method, a mask pattern of the fine grooves 40 can be formed in the first mask film 20.

In a third embodiment, an aluminum film 60 is first prepared, and anodizing of this aluminum film 60 is performed in an acidic electrolyte solution. That is, electrolysis is performed in an acidic electrolyte solution using the aluminum film 60 as an anode. When the aluminum film 60 is anodized in an acidic electrolyte solution as described above, an oxide film is first formed on the surface of the aluminum film 60, and since this oxide film is processed by an acid, recesses having high regularity in arrangement are formed on the surface of the oxide film. In addition, when the electrolysis is continuously carried out, the formation of the recesses is facilitated to etch the aluminum film 60 and that, as a result, fine holes 61 having high regularity in arrangement are formed in the aluminum film 60.

Since the size of each of the fine holes 61, the arrangement intervals therebetween, and the like can be controlled, for example, by changing a supply voltage, type of electrolyte, and concentration thereof, in this embodiment, a hole pattern of the fine holes 61 corresponding to the antireflection grating 12 is formed in the aluminum film 60.

The aluminum film 60 having the hole pattern of the fine holes 61 is disposed on the model material 10 (FIG. 3A), and over this aluminum film 60, the first mask film 20 is formed from silicon dioxide, chromium, or the like (FIG. 3B). When the aluminum film 60 is removed after the first mask film 20 is formed, parts of the first mask film 20 formed on the aluminum film 60 are removed together therewith, and on the model material 10, the first mask film 20 remains only at places corresponding to the fine holes 61 of the aluminum film 60. Consequently, the first mask film 20 is formed to have a mask pattern of the fine grooves 40 corresponding to the antireflection grating 12 (FIG. 3C).

Since the first mask film 20 having the mask pattern of the fine grooves 40 is formed using the aluminum film 60 having the hole pattern of the fine holes 61, steps of applying a resist by a coating apparatus, drawing an original pattern by an exposure apparatus, and developing an original pattern by a developing apparatus can be omitted, and as a result, the process for forming the antireflection grating 12 can be simplified.

The aluminum film 60 having the hole pattern of the fine holes 61 is disposed on the model material 10. Alternatively, the hole pattern of the fine holes 61 may be formed in the aluminum film 60 by the steps of first forming the aluminum film 60 on the model material 10, dipping the model material 10 in an acidic electrolyte solution together with the aluminum film 60, and then anodizing the aluminum film 60.

Heretofore, the embodiments of the present invention were described. In the embodiments described above, the case in which the antireflection grating is formed on the surface of the model material for an optical member is described by way of example. However, in addition to the case described above, the method can be broadly applied to the cases in which a fine grating is formed on a surface of a substrate.

Although the present invention has been explained by way of the embodiments described above, it should be understood to the ordinary skilled person in the art that the invention is not limited to the embodiments, but rather that various changes or modifications thereof are possible without departing from the spirit of the invention. Accordingly, the scope of the invention shall be determined only by the appended claims and their equivalents.

1. A method for forming a fine grating, the method comprising:
forming a first mask film having a pattern of fine grooves on a surface of a substrate;
forming a second mask film having fine recess portions over the first mask film;
etching the second mask film; and
etching parts of the substrate which are exposed through the recess portions by etching of the second mask film.

2. The method of claim 1, wherein the pattern of fine grooves corresponds to the fine grating.

3. The method of claim 2, wherein the fine recess portions have a smaller width than that of the fine grooves and are disposed at positions at which the fine grooves of the first mask film are located.

4. The method of claim 1, wherein the fine recess portions reach the surface of the substrate while widths of the fine recess portions are each approximately uniformly maintained.

5. The method of claim 1, wherein the etching the exposed parts of the substrate forms the fine grating.

6. The method of claim 1, wherein the second mask film is formed of silicon dioxide and is etched by dry etching so that the fine recess portions reach the surface of the substrate while widths of the recess portions are each approximately uniformly maintained.

7. The method of claim 1, wherein the second mask film is processed by ion milling for etching so that the fine recess portions reach the surface of the substrate while widths of the recess portions are each approximately uniformly maintained.

8. A method for forming a fine grating, the method comprising:
providing a metal film having a plurality of fine holes;
disposing the metal film on a surface of a substrate;
disposing a mask film on top of the metal film and the substrate;
removing the metal film; and
etching the substrate.

9. The method of claim 8, where the metal film is comprised of aluminum.

10. The method of claim 9 where the plurality of holes are formed by anodization.

11. The method of claim 10, where the plurality of holes have a pattern corresponding to the fine grating.

12. The method of claim 12, wherein, the metal film is removed so as to form a mask having fine grooves.

13. A method for forming a fine grating, the method comprising:
forming a metal film having a plurality of fine holes on the substrate;
disposing a mask film on top of the metal film and the substrate;
removing the metal film; and
etching the substrate.

14. The method of claim 13, wherein the plurality of holes is arranged in a pattern.

15. The method of claim 13, wherein the metal film comprises aluminum.

16. The method of claim 15, wherein the hole pattern is formed by anodization.

17. The method of claim 13, wherein the hole pattern corresponds to the fine grating.

18. The method of claim 13, wherein, the metal film is removed so as to form a mask having fine grooves.
